(19) United States
(12) Patent Application Publication
(10) Pub. No.: US 2009/0096055 A1
(43) Pub. Date: Apr. 16, 2009

(54) METHOD TO FORM CMOS CIRCUITS WITH SUB 50NM STI STRUCTURES USING SELECTIVE EPITAXIAL SILICON POST STI ETCH

(75) Inventors: Clint L. Montgomery, Coppell, TX (US); Brian K. Kirkpatrick, Allen, TX (US); Weize Xiong, Plano, TX (US); Steven L. Prins, Fairview, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/187,958

(22) Filed: Aug. 7, 2008

Related U.S. Application Data
(60) Provisional application No. 60/980,325, filed on Oct. 16, 2007.

(51) Int. Cl. H01L 21/762; H01L 23/00

(52) U.S. Cl. 257/510; 438/429; 257/E23.002; 257/E21.545

(57) ABSTRACT

An STI field oxide element in an IC which includes a layer of epitaxial semiconductor on sidewalls of the STI trench to increase the width of the active area adjacent to the STI trench and decrease a width of dielectric material in the STI trench is disclosed. STI etch residue is removed from the STI trench surface prior to growth of the epitaxial layer. The epitaxial semiconductor composition is matched to the composition of the adjacent active area. The epitaxial semiconductor may be undoped or doped to match the active area. The STI trench with the epitaxial layer is compatible with common STI passivation and fill processes. The thickness of the as-grown epitaxial semiconductor layer is selected to provide a desired active area width or a desired STI dielectric width.

### FIELD OF THE INVENTION

This invention relates to the field of integrated circuits. More particularly, this invention relates to methods to improve shallow trench isolation.

### BACKGROUND OF THE INVENTION

It is well known that lateral dimensions of components in advanced complementary metal oxide semiconductor (CMOS) integrated circuits (ICs) are shrinking with each new fabrication technology node, as articulated by Moore's Law. Transistors in CMOS ICs are electrically isolated from each other by elements of field oxide formed by shallow trench isolation (STI) processes. In dense circuits of conventional planar metal oxide semiconductor (MOS) transistors, it is desirable to have a width ratio of silicon to field oxide above 0.85:1 with field oxide between 250 to 350 nanometers thick. In dense circuits of three dimensional transistors, commonly known as finFETs, it is desirable to have a width ratio of silicon to field oxide above 1.5:1 with isolation trenches between 100 and 150 nanometers deep. Photolithographic processes available during each fabrication technology node are typically capable of printing lines and spaces at the pitch (total width of one line and one space) of the dense circuits with approximately 1:1 width ratios. STI processes include etches and oxidation operations which typically consume 10 nanometers or more of silicon on each side of an element of field oxide, undesirably reducing the silicon to field oxide ratio below an optimum value for circuit performance. Fabricating dense circuits at the 45 nanometer node and beyond becomes increasingly difficult due to conflicting constraints between photolithographic and STI processes.

Accordingly, a field oxide fabrication process which can attain a ratio of silicon to field oxide between 0.85:1 and 1:1 at a pitch of less than 100 nanometers for field oxide between 250 and 350 nanometers thick, and which can attain a ratio of silicon to field oxide above 1.5:1 at a pitch of less than 100 nanometers for isolation trenches between 100 and 150 nanometers deep, is desired.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

The instant invention provides an improved shallow trench isolation (STI) element of field oxide in an integrated circuit (IC) which includes a layer of epitaxial semiconductor on sidewalls of the STI trench which increase the width of the active area in the IC adjacent to the STI trench and decreases a width of dielectric material in the STI trench. A pre-epitaxial growth cleanup process removes STI etch residue from the STI trench surface. The epitaxial semiconductor composition is matched to the composition of the adjacent active area. The epitaxial semiconductor may be undoped or doped to match the active area. After growth of the epitaxial semiconductor layer on the STI trench surface, the epitaxial layer is electrically passivated using known processes, followed by deposition of an STI fill dielectric and completion of the STI structures, also using known processes. The thickness of the as-grown epitaxial semiconductor layer is selected to provide a desired active area width or a desired STI dielectric width.

An advantage of the instant invention is ICs with structures including active areas and STI field oxide elements with ratios of silicon to field oxide between 0.85:1 and 1:1 with field oxide between 250 and 350 nanometers thick on pitches of less than 100 nanometers may be fabricated using photolithographic patterns with ratios of line width to space width less than 1:1. A further advantage is ICs with active areas and STI field oxide elements with ratios of silicon to field oxide greater than 1.5:1 with isolation trenches between 100 and 150 nanometers deep on pitches of less than 100 nanometers, may be fabricated using photolithographic processes of similar capabilities as described in the first advantage.

### DESCRIPTION OF THE VIEWS OF THE DRAWING

FIG. 1A through FIG. 1F are cross-sections of an IC containing an active area and STI trenches formed according to the instant invention, depicted in successive stages of fabrication.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

The instant invention addresses a need for a field oxide fabrication process which can attain a silicon to field oxide ratio between 0.85:1 and 1:1 for planar MOS transistors, and addresses a need for a field oxide fabrication process which can attain a silicon to field oxide ratio above 1.5:1 for finFETs, at a pitch of less than 100 nanometers. The instant invention provides a layer of epitaxial semiconductor on sidewalls of a shallow trench isolation (STI) element of field oxide which increase a width of an active area adjacent to an STI trench and decreases a width of dielectric material in the STI trench. The epitaxial semiconductor may be silicon or silicon-germanium, to match the active area. Furthermore, the epitaxial semiconductor may be undoped or doped to match the active area. After growth of the epitaxial semiconductor layer on the STI trench sidewall, an electrical passivation process, such as growth of a liner oxide, is performed on an exposed surface of the epitaxial semiconductor layer, using known processes, followed by deposition of an STI fill dielectric and completion of the STI structures, also using known processes. A thickness of the epitaxial semiconductor layer is selected to provide a desired active area width or a desired STI dielectric region width.

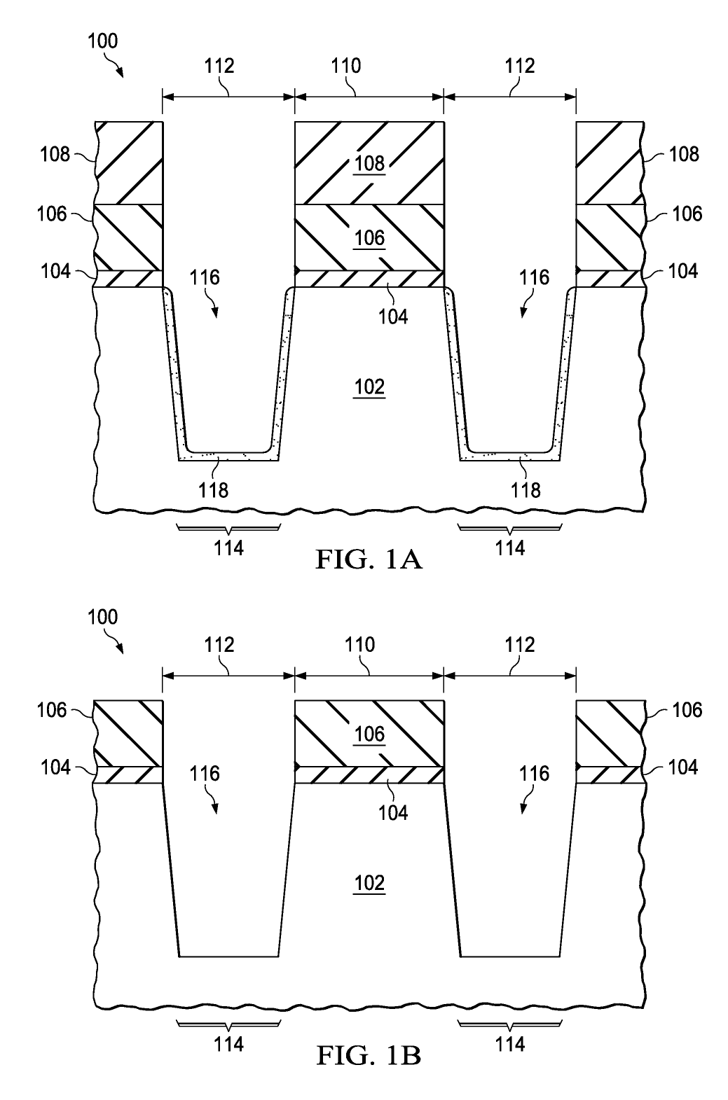

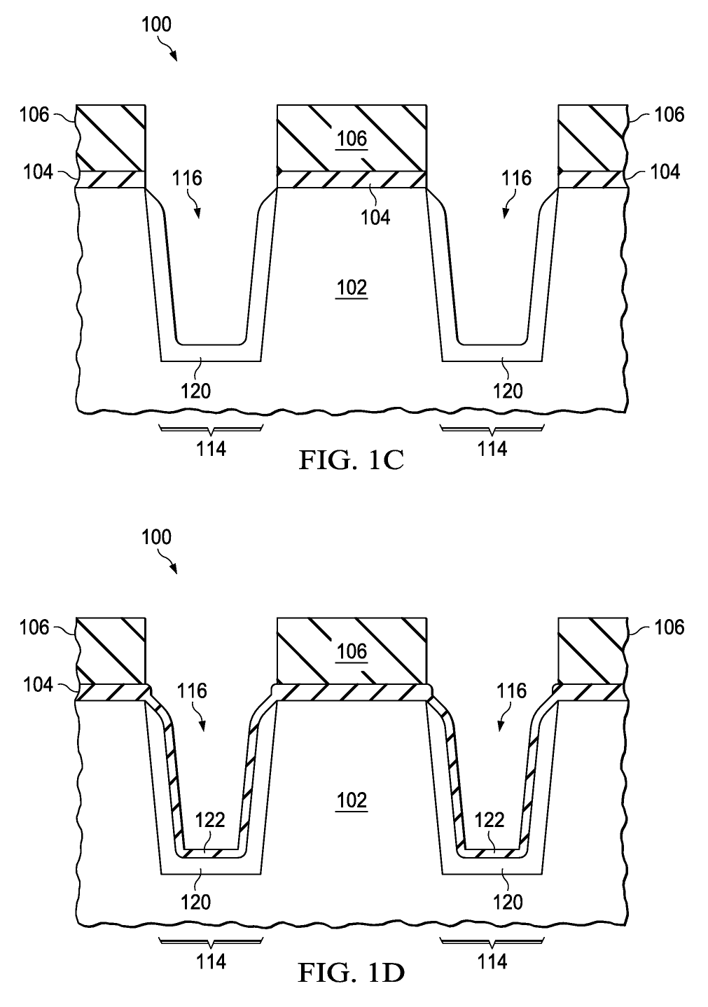

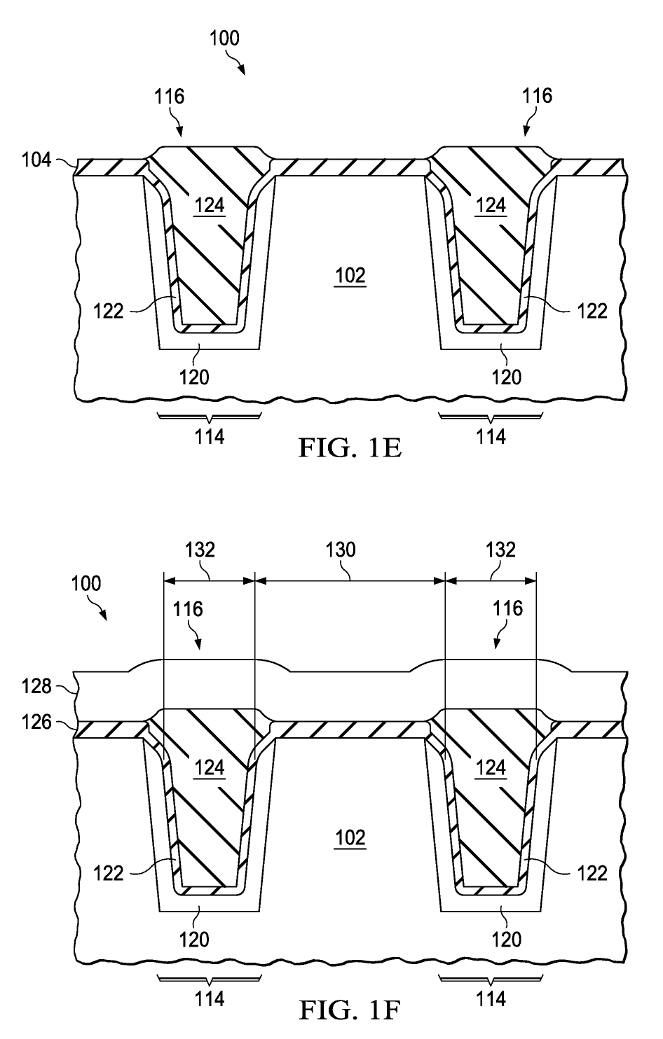

FIG. 1A through FIG. 1F are cross-sections of an IC containing an active area and STI trenches formed according to the instant invention, depicted in successive stages of fabrication. Referring to FIG. 1A, the IC (100) is formed in a semiconductor substrate (102), which may be p-type single crystal silicon, or silicon-germanium, or a hybrid orientation technology (HOT) wafer having regions with different crystal orientations, or other semiconductor substrate structure suitable for forming the IC (100). An isolation pad layer (104), typically thermally grown silicon dioxide between 2 and 40 nanometers thick, is formed on a top surface of the substrate (102). It is within the scope of the instant invention to form the isolation pad layer (104) of other materials at other thicknesses and by other processes. An isolation hardmask layer (106), typically silicon nitride between 50 and 200 nanometers thick, and commonly deposited by low pressure chemical vapor deposition (LPCVD) or plasma enhanced chemical vapor deposition (PECVD) processes, is formed on a top surface of the isolation pad layer (104). An isolation photoresist pattern (108) is formed on a top surface of the isolation hardmask layer (106) using known photolithographic methods, in which a photoresist line width (110) is between 100% and 115% ofa space width (112). STI regions (114) for forming trenches in the substrate (102) are exposed by the isolation photoresist pattern (108).

Still referring to FIG. 1A, an STI trench etch process sequence is performed on the IC (100). Hardmask material in the isolation hardmask layer (106) is removed in the STI regions (114) during a first phase of the STI trench etch process sequence by known dielectric etching methods, for example reactive ion etching (RIE) using fluorine containing plasmas. Similarly, isolation pad layer material in the isolation pad layer (104) is removed in the STI regions (114) during a subsequent phase of the STI trench etch process sequence by known dielectric etching methods, including RIE. Substrate material in the semiconductor substrate (102) is removed in the STI regions (114) during a later phase of the STI trench etch process sequence by known semiconductor etching methods, including RIE, to form STI trenches (116) in the substrate (102). STI etch residue (118), possibly including organic polymers, remains on surfaces of the STI trenches (116) after the STI trench etch process sequence is completed. The isolation photoresist pattern (108) is removed after the STI trench etch process sequence is completed, commonly by exposing the IC (100) to an oxygen containing plasma, followed by a wet cleanup to remove any organic residue from the top surface of the isolation hardmask layer (106).

FIG. 1B depicts the IC (100) after a pre-epitaxial cleanup process which removes the STI etch residue from exposed surfaces of the STI trenches (116). In one embodiment, the pre-epitaxial cleanup process includes exposing the IC (100) to wet chemical etchants to remove the STI etch residue, wherein a final etchant is a form of dilute hydrofluoric acid (HF) or a buffered HF solution. In an alternate embodiment, the pre-epitaxial cleanup process includes heating the IC (100) between 750 and 1050 C for 3 minutes to 1 hour to desorb the STI etch residue.

FIG. 1C depicts the IC (100) after a selective epitaxial growth process in which an epitaxial semiconductor layer (120) is grown on the exposed surfaces of the STI trenches (116). Growth conditions are selected such that substantially no semiconductor material is grown on exposed surfaces of the isolation pad layer (104) or the isolation hardmask layer (106). For example, epitaxial silicon may be selectively grown by placing the IC (100) in a reaction chamber, heating the IC (100) to 650 to 750 C, flowing forming gas at 3 to 30 slm into the reaction chamber, flowing dichlorosilane gas at 30 to 300 sccm into the reaction chamber, and flowing HCl gas at 20 to 250 sccm into the reaction chamber while maintaining a pressure in the reaction chamber between 3 and 30 torr. In a preferred embodiment, a thickness of the epitaxial semiconductor layer (120) is between 2 and 10 nanometers, such that a desired width of an active area between to the STI trenches (116) is obtained, or a desired width of dielectric material in the STI trenches (116) is obtained. The epitaxial semiconductor layer (120) may be silicon or silicon-germanium, as needed to match a composition of the substrate (102). The epitaxial semiconductor layer (120) may be substantially undoped, or may be doped to match a doping density and doping type in the substrate (102). In an alternate embodiment, a doping density and doping type in the epitaxial semiconductor layer (120) may be adjusted to optimize a performance parameter of a metal oxide semiconductor transistor formed in the active area between to the STI trenches (116).

FIG. 1D depicts the IC (100) after a process to electrically passivate exposed surfaces of the epitaxial semiconductor layer (120). In one embodiment, depicted in FIG. ID, 1 to 5 nanometers of silicon dioxide (122) may be grown on the exposed surfaces of the epitaxial semiconductor layer (120) by known thermal oxidation processes. In an alternate embodiment, the exposed surfaces of the epitaxial semiconductor layer (120) may be electrically passivated by forming a layer of silicon dioxide, silicon nitride, or silicon oxynitride in the STI trenches (116) by any of several known processes. In yet another embodiment, the exposed surfaces of the epitaxial semiconductor layer (120) may be passivated using known cleaning and etching methods, without recourse to a dielectric layer formed on the exposed surfaces. Other methods of electrically passivating the exposed surfaces of the epitaxial semiconductor layer (120) are within the scope of the instant invention.

FIG. 1E depicts the IC (100) after formation of a STI dielectric fill elements (124) in the STI trenches (116) by known methods. In one embodiment, an STI fill material, typically silicon dioxide, is deposited in the STI trenches (116), commonly by sub-atmospheric chemical vapor deposition (SACVD) or high density plasma (HDP) processes. Subsequent processing steps, such as densification of the STI fill material in an oxidizing ambient at temperatures above 600 C may consume semiconductor material at a surface of the epitaxial layer (120). Unwanted STI fill material on a top surface of the etched hardmask layer is removed, typically by chemical mechanical polishing (CMP) processes. Other processes of forming the STI dielectric fill elements (124) are within the scope of the instant invention. The STI hardmask material is removed, for example by known etching methods involving phosphoric acid.

FIG. 1F depicts the IC (100) after formation of elements of an MOS transistor in the active area between to the STI trenches (116). The STI isolation pad layer is removed from the top surface of the substrate (102), typically by known etching methods involving buffered or dilute HF. A gate dielectric layer (126), typically silicon dioxide, nitrogen doped silicon dioxide, silicon oxy-nitride, hafnium oxide, layers of silicon dioxide and silicon nitride, or other insulating material, commonly between 1.0 and 2.5 nanometers thick, is formed on the top surface of the substrate (102). An MOS gate layer (128), typically polycrystalline silicon, commonly known as poly silicon, or less commonly, a metallic material, is formed on top surfaces of the gate dielectric layer (126) and STI dielectric fill elements (124). In some embodiments, an MOS gate is formed in the MOS transistor by forming a gate of polysilicon and replacing the polysilicon by a metal in subsequent processing. An as-grown thickness of the epitaxial semiconductor layer (120) is preferably selected to provide a desired active area width (130), defined as a lateral width of the substrate (102) and the epitaxial layers (120), and/or a desired field oxide width (132), defined as a lateral separation between the epitaxial layers (120). In one embodiment, the STI trench etch process sequence may be adjusted to account for epitaxial layer material on bottom surfaces of the STI trenches (116).

The formation of the epitaxial layers (120) to increase the active area width and reduce the STI dielectric width is advantageous because a width of the active area (130) is desirably increased to a value that is approximately optimum for circuit performance.

What is claimed is:

1. An integrated circuit comprising a shallow trench isolation (STI) element of field oxide that includes an epitaxial semiconductor layer on surfaces of an STI trench in said STI element of field oxide.

2. The integrated circuit of claim 1, in which said epitaxial semiconductor layer is further comprised of silicon between 2 and 10 nanometers thick.

3. The integrated circuit of claim 1, in which said epitaxial semiconductor layer is further comprised of silicon-germanium between 2 and 10 nanometers thick.

4. The integrated circuit of claim 1, in which a width of dielectric material in said STI trench is less than 50 nanometers.

5. The integrated circuit of claim 1, in which a doping density of said epitaxial semiconductor layer is substantially equal to a doping density of a substrate material adjacent to said STI trench.

6. The integrated circuit of claim 1, in which said epitaxial semiconductor layer is substantially undoped.

7. An integrated circuit, comprising:
a first STI element of field oxide, further comprising a first epitaxial semiconductor layer on surfaces of a first STI trench in said first STI element of field oxide; and
a second STI element of field oxide, further comprising a second epitaxial semiconductor layer on surfaces of a second STI trench in said second STI element of field oxide.

8. The integrated circuit of claim 7, in which said first epitaxial semiconductor layer and said second epitaxial semiconductor layer are further comprised of silicon between 2 and 10 nanometers thick.

9. The integrated circuit of claim 7, in which said first epitaxial semiconductor layer and said second epitaxial semiconductor layer are further comprised of silicon-germanium between 2 and 10 nanometers thick.

10. The integrated circuit of claim 7, in which:
a width of dielectric material in said first STI trench is less than 50 nanometers; and
a width of dielectric material in said second STI trench is less than 50 nanometers.

11. The integrated circuit of claim 10, in which:
a center-to-center distance between said first STI element of field oxide and said second STI element of field oxide is not more than 93 nanometers; and
a width of active area between said first STI element of field oxide and said second STI element of field oxide is not less than 43 nanometers.

12. The integrated circuit of claim 7, in which a doping density of said first epitaxial semiconductor layer and a doping density of said second epitaxial semiconductor layer are substantially equal to a doping density of a substrate material between said first STI element of field oxide and said second STI element of field oxide.

13. The integrated circuit of claim 7, in which:
said first epitaxial semiconductor layer is substantially undoped; and
said second epitaxial semiconductor layer is substantially undoped.

14. A method of forming an integrated circuit, comprising the steps of:
forming a first STI element of field oxide, by a process further comprising the steps of:
etching a first STI trench in a substrate of said integrated circuit;
removing a first layer of STI etch residue from surfaces of said first STI trench;
forming a first epitaxial semiconductor layer on said surfaces of said first STI trench in a manner whereby substantially no semiconductor material is formed on exposed surface of dielectric materials in said integrated circuit;
electrically passivating an exposed surface of said first epitaxial semiconductor layer; and
filling said first STI trench with a first STI dielectric material; and
forming a second STI element of field oxide, by a process further comprising the steps of:
etching a second STI trench in a substrate of said integrated circuit;
removing a second layer of STI etch residue from surfaces of said second STI trench;
forming a second epitaxial semiconductor layer on said surfaces of a second STI trench in a manner whereby substantially no semiconductor material is formed on exposed surface of dielectric materials in said integrated circuit;
electrically passivating an exposed surface of said second epitaxial semiconductor layer; and
filling said second STI trench with a second STI dielectric material.

15. The method of claim 14, in which said first epitaxial semiconductor layer and said second epitaxial semiconductor layer are further comprised of silicon between 2 and 10 nanometers thick.

16. The method of claim 14, in which said first epitaxial semiconductor layer and said second epitaxial semiconductor layer are further comprised of silicon-germanium between 2 and 10 nanometers thick.

17. The method of claim 14, in which:
a width of said first STI dielectric material in said first STI trench is less than 50 nanometers; and
a width of said second STI dielectric material in said second STI trench is less than 50 nanometers.

18. The method of claim 17, in which:
a center-to-center distance between said first STI element of field oxide and said second STI element of field oxide is not more than 93 nanometers; and
a width of active area between said first STI element of field oxide and said second STI element of field oxide is not less than 43 nanometers.

19. The method of claim 14, in which a doping density of said first epitaxial semiconductor layer and a doping density of said second epitaxial semiconductor layer are substantially equal to a doping density of a substrate material between said first STI element of field oxide and said second STI element of field oxide.

20. The method of claim 14, in which:
said first epitaxial semiconductor layer is substantially undoped; and
said second epitaxial semiconductor layer is substantially undoped.
